(19) United States
(12) Patent Application Publication
(10) Pub. No.: US 2021/0088562 A1
(43) Pub. Date: Mar. 25, 2021

(54) METHOD, APPARATUS AND DEVICE FOR DETECTING ABNORMALITY OF ELECTRIC SIGNAL

(71) Applicant: Hangzhou Vango Technologies, Inc., Hangzhou (CN)

(72) Inventors: Boqiang WU, Hangzhou (CN); NICK NIANXIONG TAN, Hangzhou (CN); Changyou MEN, Hangzhou (CN)

(73) Assignee: Hangzhou Vango Technologies, Inc., Hangzhou (CN)

(21) Appl. No.: 16/798,407

(22) Filed: Feb. 23, 2020

(30) Foreign Application Priority Data
Sep. 20, 2019 (CN) 201910894874.9

(51) Int. Cl. G01R 19/165; G01R 19/00

(52) U.S. Cl. CPC G01R 19/1659; G16Y 40/10; G01R 19/0015

(57) ABSTRACT

A method, an apparatus, and a device for detecting abnormality of an electric signal. The method includes: sampling the electric signal at each of sampling points in unit sampling intervals, to obtain a sampling value; counting abnormal sampling points within each of the unit sampling intervals to acquire a quantity of abnormal points, where each of the abnormal sampling points is one of the sampling points at which the sampling value is out of a threshold range of the electric signal; determining each of the unit sampling intervals, within which the quantity of abnormal points is larger than a quantity-of-abnormal-point threshold, to be an abnormal unit sampling interval; counting the abnormal unit sampling intervals that are consecutive, to acquire a quantity of consecutive abnormal intervals; and determining that the electric signal is abnormal, in response to the quantity of consecutive abnormal intervals being greater than a quantity-of-abnormal-interval threshold.

The present disclosure claims priority to Chinese Patent Application No. 201910894874.9, titled “METHOD, APPARATUS AND DEVICE FOR DETECTING ABNORMALITY OF ELECTRIC SIGNAL”, filed on Sep. 20, 2019 with the China National Intellectual Property Administration, which is incorporated herein by reference in its entirety.

### FIELD

The present disclosure relates to the technical field of detecting abnormal events in a power grid, and in particular to a method, an apparatus, and a device for detecting abnormality of an electric signal.

### BACKGROUND

With ubiquitous power Internet of Things being proposed in concepts and constructed, each data acquisition device in a power system serves as a sensing node in a sensing layer of the ubiquitous electricity Internet of Things, and needs to have a basic function of detecting abnormal events in a power grid.

Electric signals in the power grid, namely, voltage signals and current signals, are original data of the power grid. The electric signals are easy to obtain, process, and calculate, and especially suitable for detecting abnormal events in the power grid, for example, overvoltage, overcurrent, undervoltage, and undercurrent. In a conventional detection method, a processed voltage signal or a processed current signal is sampled, and then compared with an upper threshold and a lower threshold. In a case that the sampling value is greater than the upper threshold, it is determined that an overvoltage or overcurrent event occurs. In a case that the sampling value is lower than the upper threshold, it is determined that an undervoltage or undercurrent event occurs. Sensitivity of detection may be tuned by adjusting the upper threshold and the lower threshold. Such method has a simple determination process and low reliability, and it is apt to cause misjudgment.

Therefore, it is urgent to address the technical issue that the conventional technology has poor reliability when detecting abnormal events in the power grid, for those skilled in the art.

### SUMMARY

In view of the above, an object of the present disclosure is to provide a method, an apparatus, and a device for detecting abnormality of an electric signal, so as to address the technical issue that the conventional technology has poor reliability when detecting abnormal events in the power grid.

A method for detecting abnormality of an electric signal is provided, including following steps. The electric signal is sampled at each of sampling points in unit sampling intervals, to obtain a sampling value. Abnormal sampling points within each of the unit sampling intervals are counted to acquire a quantity of abnormal points, where each of the abnormal sampling points is one of the sampling points at which the sampling value is out of a threshold range of the electric signal. Each of the unit sampling intervals, within which the quantity of abnormal points is larger than a quantity-of-abnormal-point threshold, is determined to be an abnormal unit sampling interval, and the abnormal unit sampling intervals that are consecutive are counted to acquire a quantity of consecutive abnormal intervals. It is determined that the electric signal is abnormal in response to the quantity of consecutive abnormal intervals being greater than a quantity-of-abnormal-interval threshold.

In one embodiment, before sampling the electric signal at each of sampling points in unit sampling intervals, the method further includes following steps. An original electric signal is obtained. A direct current component in the original electric signal is filtered out, to obtain a sinusoidal alternating current component. The sinusoidal alternating current component is full-wave rectified, to obtain the electric signal.

In one embodiment, obtaining the original signal includes a following step. An original current signal is obtained via a current sensor, or an original voltage signal is obtained via a voltage sensor.

In one embodiment, determining that the electric signal is abnormal in response to the quantity of consecutive abnormal intervals being greater than the quantity-of-abnormal-interval threshold includes following steps. It is determined that the quantity of consecutive abnormal intervals is greater than the quantity-of-abnormal-interval threshold. The sampling value of each abnormal sampling point of the abnormal unit sampling intervals is compared with an upper limit and a lower limit of the threshold range. It is determined that the abnormal unit sampling intervals are overvoltage or overcurrent sampling intervals, and the electric signal is abnormal due to overvoltage or overcurrent, in response to the sampling value of each abnormal sampling point of the abnormal unit sampling intervals being greater than the upper limit. It is determined that the abnormal unit sampling intervals are undervoltage or undercurrent sampling intervals, and the electric signal is abnormal due to undervoltage or undercurrent, in response to the sampling value of each abnormal sampling point of the abnormal unit sampling intervals being smaller than the lower limit.

An apparatus for detecting abnormality of an electric signal, including a sampling module, a first counting module, a second counting module, and a determination module.

The sampling module is configured to sample the electric signal at each of sampling points in unit sampling intervals, to obtain a sampling value.

The first counting module is configured to count abnormal sampling points within each of the unit sampling intervals to acquire a quantity of abnormal points, where each of the abnormal sampling points is one of the sampling points at which the sampling value is out of a threshold range of the electric signal.

The second counting module is configured to determine each of the unit sampling intervals, within which the quantity of abnormal points is larger than a quantity-of-abnormal-point threshold, to be an abnormal unit sampling interval, and count the abnormal unit sampling intervals that are consecutive to acquire a quantity of consecutive abnormal intervals.

The determination module is configured to determine that the electric signal is abnormal in response to the quantity of consecutive abnormal intervals being greater than a quantity-of-abnormal-interval threshold.

In one embodiment, the apparatus further comprises a filtering module and a full-wave rectification module. The filtering module is configured to obtain an original electric signal, and filter out a direct current component in the original electric signal to obtain a sinusoidal alternating current component. The full-wave rectification module is configured to full-wave rectify the sinusoidal alternating current component, to obtain the electric signal.

In one embodiment, the filtering module includes an original current signal obtaining unit, or an original voltage signal obtaining unit. The original current signal obtaining unit is configured to obtain an original current signal via a current sensor. The original voltage signal obtaining unit is configured to obtain an original voltage signal via a voltage sensor.

In one embodiment, the determining module includes a determination unit, a comparison unit, an overvoltage or overcurrent determination unit, and an undervoltage or undercurrent determination unit.

The determination unit is configured to determine that the quantity of consecutive abnormal intervals is greater than the quantity-of-abnormal-interval threshold.

The comparison unit is configured to compare the sampling value of each abnormal sampling point of the abnormal unit sampling intervals with an upper limit and a lower limit of the threshold range.

The overvoltage or overcurrent determination unit is configured to determine that the abnormal unit sampling intervals are overvoltage or overcurrent sampling intervals, and the electric signal is abnormal due to overvoltage or overcurrent, in response to the sampling value of each abnormal sampling point of the abnormal unit sampling intervals being greater than the upper limit.

The undervoltage or undercurrent determination unit is configured to determine that the abnormal unit sampling intervals are undervoltage or undercurrent sampling intervals, and the electric signal is abnormal due to undervoltage or undercurrent, in response to the sampling value of each abnormal sampling point of the abnormal unit sampling intervals being smaller than the lower limit.

A device for detecting abnormality of an electric signal is further provided, including a memory and a processor. The memory is configured to store a computer program. The computer program when executed by the processor configures the device to implement the aforementioned method for detecting abnormality of the electric signal.

It can be seen that according to the method, the electric signal is sampled at each of the sampling points in the unit sampling intervals, to obtain the sampling value. After the sampling, the sampling point at which the sampling value is out of the threshold range of the electric signal is determined to be the abnormal sampling point. The abnormal sampling points within each of the unit sampling intervals are counted to acquire the quantity of abnormal points. It is determined whether the quantity of abnormal points is larger than a quantity-of-abnormal-point threshold, and a positive determination indicates that there are many abnormal points. That is, most part of the electric signals is not within the threshold range. The unit sampling interval, within which the quantity of abnormal points is larger than a quantity-of-abnormal-point threshold, is determined to be the abnormal unit sampling interval. The consecutive abnormal sampling intervals are counted to obtain the quantity of consecutive abnormal intervals. Many consecutive abnormal sampling intervals, it indicates a great possibility of an abnormal event in the power grid. The quantity of consecutive abnormal intervals is compared with the quantity-of-abnormal-interval threshold. In a case that the quantity of consecutive abnormal intervals is greater than the quantity-of-abnormal-interval threshold, it is determined that the electric signal is abnormal. That is, there is an abnormal event of the power grid. The method addresses the defect that the conventional technology has poor reliability when detecting abnormal events in the power grid.

The apparatus and the device for detecting abnormality of an electric signal according to embodiments of the present disclosure also have the aforementioned beneficial effects.

### BRIEF DESCRIPTION OF THE DRAWINGS

For clearer illustration of the technical solutions according to embodiments of the present disclosure or conventional techniques, hereinafter are briefly described the drawings to be applied in embodiments of the present disclosure or conventional techniques. Apparently, the drawings in the following descriptions are only some embodiments of the present disclosure, and other drawings may be obtained by those skilled in the art based on the provided drawings without creative efforts.

FIG. 1 is a flowchart of a method for detecting abnormality of an electric signal according to an embodiment of the present disclosure;

FIG. 2 is a flowchart of a method for detecting abnormality of an electric signal according to another embodiment of the present disclosure;

FIG. 3 is a waveform diagram of an electric signal according to an embodiment of the present disclosure;

FIG. 4 is a flowchart of a method for detecting abnormality of an electric signal according to another embodiment of the present disclosure;

FIG. 5 is a schematic structural diagram of an apparatus for detecting abnormality of an electric signal according to an embodiment of the present disclosure; and

FIG. 6 is a schematic structural diagram of a device for detecting abnormality of an electric signal according to an embodiment of the present disclosure.

### DETAILED DESCRIPTION

To make the object, technical solutions and advantages of the present application clearer, hereinafter technical solutions in embodiments of the present disclosure are described clearly and completely in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

### First Embodiment

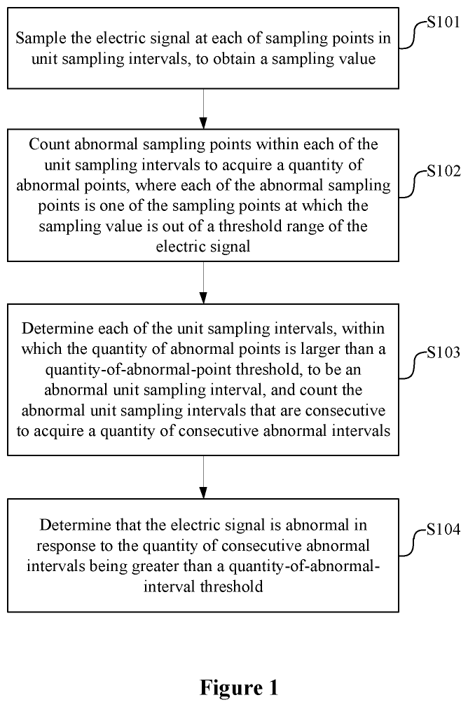

Reference is made to FIG. 1, which is a flowchart of a method for detecting abnormality of an electric signal according to an embodiment of the present disclosure. The method includes steps S101 to S104.

In step S101, an electric signal is sampled at each of sampling points in unit sampling intervals, to obtain a sampling value.

In one embodiment, the electric signal is obtained from a power grid to be detected. A frequency of obtaining the electric signal is not limited in this embodiment. For example, the electric signal may be obtained in real time from the power grid to be detected, or obtained after each preset interval from the power grid to be detected. The electric signal may be a voltage signal of the power grid to be detected, or a current signal of the power grid to be detected. The electric signal is sampled according to a preset unit sampling interval. The unit sampling interval is configured to determine a length of each sampling interval, and a length of the unit sampling interval is a positive-integer multiple of a half fundamental period. A specific length of the unit sampling interval is not limited in this embodiment. For example, the length of the unit sampling interval may be a half fundamental period. A fundamental frequency of a power grid in China is 50 Hz, thereby a period thereof is 20 milliseconds, and the half fundamental period is 10 milliseconds. In such case, the length of the unit sampling interval may be 10 milliseconds. Alternatively, the length of the unit sampling interval may also be one fundamental period, namely, 20 milliseconds. Assuming other preset thresholds are identical, the longer the unit sampling interval is, the lower the detection sensitivity is, and the shorter the unit sampling interval is, the higher the detection sensitivity is. The length of the unit sampling interval may be set according to a specific situation. For example, in a case that it is required to finely detect the power grid to be detected, the length of the unit sampling interval may be small, such as a half fundamental period. In a case that it is required to coarsely detect the power grid to be detected, the length of the unit sampling interval may be large, such as two fundamental periods. A sampling frequency, a moment at which the sampling starts, and a moment at which the sampling time ends are not limited in this embodiment. For example, the moment at which the sampling starts may be a beginning of the unit sampling interval, the moment at which the sampling ends may be an end of the unit sampling interval, and the sampling frequency may be may be ten times per unit sampling interval.

In step S102, abnormal sampling points within each of the unit sampling intervals are counted to acquire a quantity of abnormal points, where each of the abnormal sampling points is one of the sampling points at which the sampling value is out of a threshold range of the electric signal.

In one embodiment, the threshold range is preset. The threshold range is compared with the sampling value, to determine whether the sampling point corresponding to the sampling value is the abnormal sampling point. The threshold range is not specifically limited in this embodiment, and may be different for different electric signals. For example, in a case that the electric signal is a current signal of the power grid to be detected, the threshold range is correspondingly a current threshold range. In a case that the electric signal is a voltage signal of the power grid to be detected, the threshold range is correspondingly a voltage threshold interval. An upper limit and a lower limit of the threshold range (where the lower limit is always less than the upper limit) are not limited in this embodiment. For example, in one embodiment, a lower limit of the current threshold range may be 5 A, and an upper limit of the current threshold range may be 10 A. In another embodiment, a lower limit of the voltage threshold range may be 5V, and an upper limit of the voltage threshold range may be 10V. The lower limits and the upper limits are different for different power grids to be detected. Specific values of the lower limits and the upper limits are based on a condition of the power grid to be detected, and are not limited in this embodiment. Assuming other preset thresholds are identical, the smaller the lower limit is and the greater the upper limit is, the lower the detection sensitivity is, and the greater the lower limit is and the smaller the upper limit is, the higher the detection sensitivity is.

The sampling value is obtained after the electric signal is sampled, and the sample value is compared with the lower limit and the upper limit. In a case that the sampling value of a sampling point is greater than the lower limit and smaller than the upper limit, the sampling point is a normal sampling point. In a case that the sampling value of a sampling point is smaller than the lower limit or greater than the upper limit, the sampling point is the abnormal sampling point. In each unit sampling interval, the sampling points at which the sampling value is out of the threshold range of the electric signal are counted, that is, the abnormal sampling points are counted, so as to acquire the quantity of abnormal points within each of the unit sampling intervals.

In step S103, each of the unit sampling intervals, within which the quantity of abnormal points is larger than a quantity-of-abnormal-point threshold, is determined to be an abnormal unit sampling interval, and the abnormal unit sampling intervals that are consecutive are counted to acquire a quantity of consecutive abnormal intervals.

In one embodiment, the quantity-of-abnormal-point threshold is preset. The quantity-of-abnormal-point threshold may be a positive integer, which is not limited in this embodiment. The quantity-of-abnormal-point threshold is compared with the acquired quantity of abnormal sampling points, so as to determine whether the unit sampling interval is the abnormal sampling interval. In one embodiment, the quantity of abnormal points being larger than the quantity-of-abnormal-point threshold indicates that there are excessive abnormal points in the unit sampling interval. That is, most part of the electric signal in such unit sampling interval is not within the threshold range, and there is a possibility of an abnormal event in the power grid. The quantity of abnormal points being less than the quantity-of-abnormal-point threshold indicates that there are few abnormal points in the unit sampling interval. That is, most part of the electric signal in such unit sampling interval is within the threshold range, and there is no abnormal event in the power grid. For example, in a case that the quantity-of-abnormal-point threshold is 10 and the quantity of abnormal points is 15, the unit sampling interval is the abnormal sampling interval. The quantity-of-abnormal-point threshold is not limited in this embodiment. Assuming that other preset thresholds are identical, the greater the quantity-of-abnormal-point threshold is, the lower the detection sensitivity is, and the smaller the quantity-of-abnormal-point threshold is, the higher the detection sensitivity is.

After the abnormal sampling interval is detected, the consecutive abnormal sampling intervals are counted, so as to obtain the quantity of consecutive abnormal intervals.

In step S104, it is determined that the electric signal is abnormal in response to the quantity of consecutive abnormal intervals being greater than a quantity-of-abnormal-interval threshold.

In one embodiment, the quantity-of-abnormal-interval threshold is preset. The quantity-of-abnormal-interval threshold may be a positive integer, which is not limited in this embodiment. The quantity-of-abnormal-interval threshold is compared with the quantity of consecutive abnormal intervals, so as to determine whether there is the abnormal event in the power grid. A specific quantity-of-abnormal-interval threshold is not limited in this embodiment. Assuming that other preset thresholds are identical, the greater the quantity-of-abnormal-interval threshold is, the lower the detection sensitivity is, and the smaller the quantity-of-abnormal-interval threshold is, the higher the detection sensitivity is. A large quantity of consecutive abnormal intervals indicates a high probability of an abnormal event in the electric signal, that is, a high probability of an abnormal event in the power grid to be detected. In a case that the quantity of consecutive abnormal intervals is greater than the quantity-of-abnormal-interval threshold, it can be determined that there is abnormality in the electric signal. That is, there is an abnormal event in the power grid to be detected.

For example, the quantity-of-abnormal-interval threshold is three. After the abnormal sampling interval is determined, the quantity of consecutive abnormal intervals is counted. In a case that the quantity of consecutive abnormal sampling intervals is two, it is considered that the electric signal fluctuates temporarily and returns normal after the fluctuation. Therefore, it is determined that there is no abnormality in the electric signal. In a case that the quantity of consecutive abnormal sampling intervals is four, it is considered that a change in the electric signal is abnormal and there is abnormality in the electric signal. That is, there is an abnormal event in the power grid to be detected.

It can be seen that according to the method, the electric signal is sampled at each of the sampling points in the unit sampling intervals, to obtain the sampling value. After the sampling, the sampling point at which the sampling value is out of the threshold range of the electric signal is determined to be the abnormal sampling point. The abnormal sampling points within each of the unit sampling intervals are counted to acquire the quantity of abnormal points. It is determined whether the quantity of abnormal points is larger than a quantity-of-abnormal-point threshold, and a positive determination indicates that indicates that there are many abnormal points. That is, most part of the electric signals is not within the threshold range. The unit sampling interval, within which the quantity of abnormal points is larger than a quantity-of-abnormal-point threshold, is determined to be the abnormal unit sampling interval. The consecutive abnormal sampling intervals are counted to obtain the quantity of consecutive abnormal intervals. Many consecutive abnormal sampling intervals, it indicates a great possibility of an abnormal event in the power grid. The quantity of consecutive abnormal intervals is compared with the quantity-of-abnormal-interval threshold. In a case that the quantity of consecutive abnormal intervals is greater than the quantity-of-abnormal-interval threshold, it is determined that the electric signal is abnormal. That is, there is an abnormal event of the power grid. The method addresses the defect that the conventional technology has poor reliability when detecting abnormal events in the power grid.

### Second Embodiment

On the basis of the first embodiment, in a process of obtaining the electric signal of the power grid to be detected, an original electric signal may be first obtained, and then the original electric signal is processed in waveform, so as to obtain the electric signal. Thereby, it is quick and convenient to determine whether the sampling point is the abnormal sampling point after the electric signal is sampled.

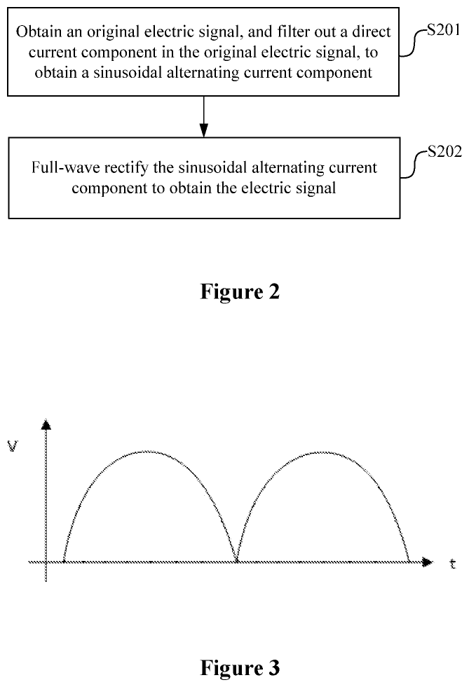

Reference is made to FIG. 2, which is a flowchart of a method for detecting abnormality of an electric signal according to another embodiment of the present disclosure. The method includes steps 201 and 202.

In step S201, an original electric signal is obtained, and a direct current component in the original electric signal is filtered out, to obtain a sinusoidal alternating current component.

In one embodiment, the original electric signal of the power grid to be detected is obtained via a sensor, and the original electric signal may be a current signal or a voltage signal. Different sensors are selected based on different original electric signal that is to be obtained. For example, in a case that a voltage signal of the power grid to be detected serves as the original electric signal, a voltage sensor may be used to obtain the voltage signal. In a case that a current signal of the power grid to be detected serves as the original electric signal, a current sensor may be used to obtain the current signal. A specific type of the voltage sensor or the current sensor is not limited in this embodiment.

After the original electric signal is obtained, the direct current component is filtered out, so as to obtain the sinusoidal alternating current component. A manner of filtering the direct current component out of the original electric signal is not limited in this embodiment. For example, the original electric signal may be filtered via a filterer circuit, so that the direct current component is filtered out while the sinusoidal alternating current component is kept.

In step S202, the sinusoidal alternating current component is full-wave rectified, to obtain the electric signal.

After the sinusoidal alternating current component is obtained, the sinusoidal alternating current component is full-wave rectified, so as to obtain the electric signal. Reference is made to FIG. 3, which is a waveform diagram of an electric signal according to an embodiment of the present disclosure. In FIG. 3, a horizontal axis represents time (t), and a vertical axis represents amplitude (v).

According to the method in this embodiment, after the original electric signal is obtained via a sensor, the direct current component is first filtered out to obtain a sinusoidal alternating current component, and then the sinusoidal alternating current component is full-wave rectified to obtain the electric signal. After processing, there is no negative value in the electric signal, so that there is no negative sampling value. It is convenient to set the threshold range after the sampling, facilitating determination of whether the sampling point is the abnormal sampling point and counting the abnormal sampling point.

### Third Embodiment

On the basis of the first and second embodiments, after determining whether the quantity of consecutive abnormal intervals is greater than the quantity-of-abnormal-interval threshold, a type of abnormality of the electric signal is further determined via the sampling value, the lower limit and the upper limit. Namely, a type of the abnormal event in the power grid to be detected is further determined for subsequent operations.

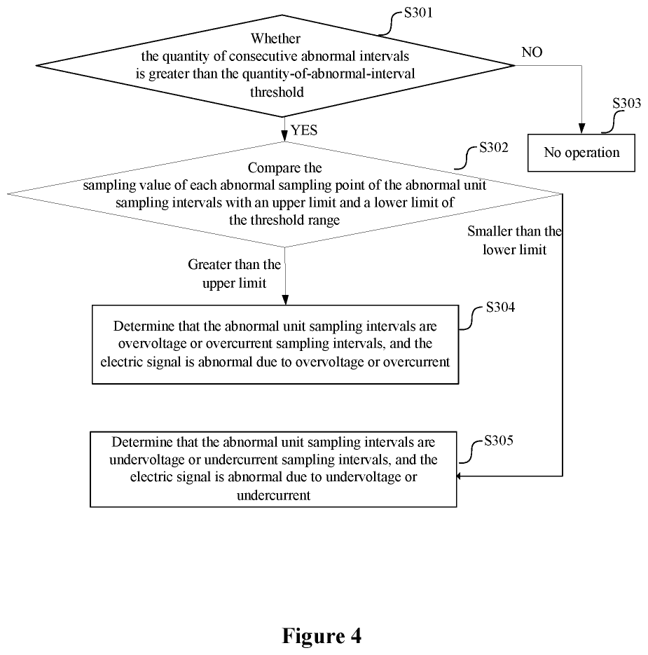

Reference is made to FIG. 4, which is a flowchart of a method for detecting abnormality of an electric signal according to another embodiment of the present disclosure. The method includes steps S301 to S305.

In step S301, it is determined whether the quantity of consecutive abnormal intervals is greater than the quantity-of-abnormal-interval threshold.

The quantity of consecutive abnormal intervals is compared with the quantity-of-abnormal-interval threshold. In a case that the quantity of consecutive abnormal intervals is not greater than the quantity-of-abnormal-interval threshold, an operation to be performed is not limited in this embodiment. In one embodiment, the process may go to step S303, which represents “no operation being performed”. In a case that the quantity of consecutive abnormal intervals is greater than the quantity-of-abnormal-interval threshold, the process goes to step S302.

In step S302, the sampling value of each abnormal sampling point of the abnormal unit sampling intervals is compared with an upper limit and a lower limit of the threshold range.

The sampling value of each abnormal sampling point of the abnormal unit sampling intervals is compared with the upper limit and the lower limit of the threshold range. A subsequent operation is performed based on a result of the comparison. In a case that the sampling value of each abnormal sampling point of the abnormal unit sampling intervals is greater than the upper limit, the process goes to step S304. In a case that the sampling value of each abnormal sampling point of the abnormal unit sampling intervals is less than the lower limit, the process goes to step S305.

In step S304, it is determined that the abnormal unit sampling intervals are overvoltage or overcurrent sampling intervals, and the electric signal is abnormal due to overvoltage or overcurrent.

The sampling value of each abnormal sampling point of the abnormal unit sampling intervals being greater than the upper limit indicates that most part of the electric signal in the consecutive abnormal unit sampling intervals is larger than the upper limit. In a case that the electric signal is the voltage signal of the power grid to be detected, it indicates that the voltage signal is too large and the abnormality is due to overvoltage. That is, there is an abnormal overvoltage event in the power grid to be detected. In a case that the electric signal is the current signal of the power grid to be detected, it indicates that the current signal is too large and the abnormality is due to overcurrent. That is, there is an abnormal overcurrent event in the power grid to be detected.

In step S305, it is determined that the abnormal unit sampling intervals are undervoltage or undercurrent sampling intervals, and the electric signal is abnormal due to undervoltage or undercurrent.

The sampling value of each abnormal sampling point of the abnormal unit sampling intervals being smaller than the lower limit indicates that most part of the electric signal in the consecutive abnormal unit sampling intervals is smaller than the lower limit. In a case that the electric signal is the voltage signal of the power grid to be detected, it indicates that the voltage signal is too small and the abnormality is due to undervoltage. That is, there is an abnormal undervoltage event in the power grid to be detected. In a case that the electric signal is the current signal of the power grid to be detected, it indicates that the current signal is too small and the abnormality is due to undercurrent. That is, there is an abnormal undercurrent event in the power grid to be detected.

According to the method in this embodiment, the type of abnormality of the electric signal can be determined via the sampling value, the lower limit and the upper limit. Namely, the type of abnormal events in the power grid to be detected is determined for subsequent operations. For example, the subsequent operation may include activating an accurate alarm, or adjusting voltage or current of the power grid to be detected.

### Fourth Embodiment

Hereinafter an apparatus for detecting abnormality of an electric signal according to an embodiment of the present disclosure is described. Description of the apparatus for detecting abnormality of the electric signal may refer to the aforementioned method for detecting abnormality of the electric signal.

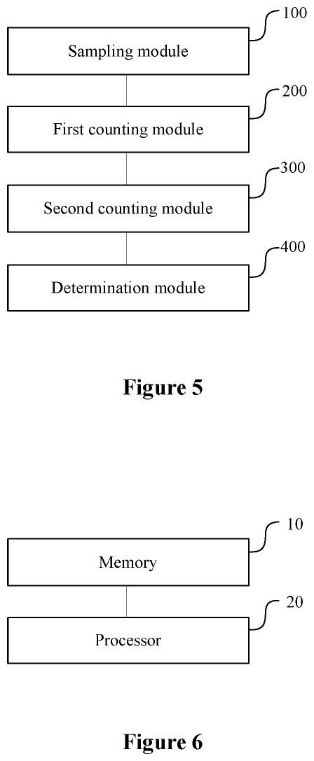

Reference is made to FIG. 5, which is a schematic structural diagram of an apparatus for detecting abnormality of an electric signal according to an embodiment of the present disclosure. The apparatus includes a sampling module 100, a first counting module 200, a second counting module 300, and a determination module 400.

The sampling module 100 is configured to sample the electric signal at each of sampling points in unit sampling intervals, to obtain a sampling value.

The first counting module 200 is configured to count abnormal sampling points within each of the unit sampling intervals, to acquire a quantity of abnormal points. Each of the abnormal sampling points is one of the sampling points at which the sampling value is out of a threshold range of the electric signal.

The second counting module 300 is configured to determine each of the unit sampling intervals, within which the quantity of abnormal points is larger than a quantity-of-abnormal-point threshold, to be an abnormal unit sampling interval. The second counting module 300 is further configured to count the abnormal unit sampling intervals that are consecutive, to acquire a quantity of consecutive abnormal intervals.

The determination module 400 is configured to determine that the electric signal is abnormal, in response to the quantity of consecutive abnormal intervals being greater than a quantity-of-abnormal-interval threshold.

It can be seen that according to the apparatus, the electric signal is sampled at each of the sampling points in the unit sampling intervals, to obtain the sampling value. After the sampling, the sampling point at which the sampling value is out of the threshold range of the electric signal is determined to be the abnormal sampling point. The abnormal sampling points within each of the unit sampling intervals are counted to acquire the quantity of abnormal points. It is determined whether the quantity of abnormal points is larger than a quantity-of-abnormal-point threshold, and a positive determination indicates that indicates that there are many abnormal points. That is, most part of the electric signals are not within the threshold range. The unit sampling interval, within which the quantity of abnormal points is larger than a quantity-of-abnormal-point threshold, is determined to be the abnormal unit sampling interval. The consecutive abnormal sampling intervals are counted to obtain the quantity of consecutive abnormal intervals. Many consecutive abnormal sampling intervals, it indicates a great possibility of an abnormal event in the power grid. The quantity of consecutive abnormal intervals is compared with the quantity-of-abnormal-interval threshold. In a case that the quantity of consecutive abnormal intervals is greater than the quantity-of-abnormal-interval threshold, it is determined that the electric signal is abnormal. That is, there is an abnormal event of the power grid. The method addresses the defect that the conventional technology has poor reliability when detecting abnormal events in the power grid.

In one embodiment, the apparatus further includes a filtering module and a full-wave rectification module.

The filtering module is configured to obtain an original electric signal, and filter out a direct current component in the original electric signal, to obtain a sinusoidal alternating current component.

The full-wave rectification module is configured to full-wave rectify the sinusoidal alternating current component, to obtain the electric signal.

In one embodiment, the filtering module includes an original current signal obtaining unit, or an original voltage signal obtaining unit. The original current signal obtaining unit is configured to obtain an original current signal via a current sensor. The original voltage signal obtaining unit is configured to obtain an original voltage signal via a voltage sensor.

In one embodiment, the determining module 400 includes a determination unit, a comparison unit, an overvoltage or overcurrent determination unit, and an undervoltage or undercurrent determination unit.

The determination unit is configured to determine that the quantity of consecutive abnormal intervals is greater than the quantity-of-abnormal-interval threshold.

The comparison unit is configured to compare the sampling value of each abnormal sampling point of the abnormal unit sampling intervals with an upper limit and a lower limit of the threshold range.

The overvoltage or overcurrent determination unit is configured to determine that the abnormal unit sampling intervals are overvoltage or overcurrent sampling intervals, and the electric signal is abnormal due to overvoltage or overcurrent, in response to the sampling value of each abnormal sampling point of the abnormal unit sampling intervals being greater than the upper limit.

The undervoltage or undercurrent determination unit is configured to determine that the abnormal unit sampling intervals are undervoltage or undercurrent sampling intervals, and the electric signal is abnormal due to undervoltage or undercurrent, in response to the sampling value of each abnormal sampling point of the abnormal unit sampling intervals being smaller than the lower limit.

### Fifth Embodiment

Hereinafter a device for detecting abnormality of an electric signal according to an embodiment of the present disclosure is described. Description of the device for detecting abnormality of the electric signal may refer to the aforementioned method for detecting abnormality of the electric signal.

Reference is made to FIG. 6, which is a schematic structural diagram of a device for detecting abnormality of an electric signal according to an embodiment of the present disclosure. The device for determining abnormality of an electric signal includes a memory 10 and a processor 20.

The memory 10 is configured to store a computer program.

The computer program when executed by the processor 20 configures the device to implement the aforementioned method for detecting abnormality of the electric signal.

The embodiments of the present disclosure are described in a progressive manner, and each embodiment places emphasis on the difference from other embodiments. Therefore, one embodiment can refer to other embodiments for the same or similar parts. Since the apparatus and the device disclosed in the embodiments both correspond to the method disclosed in the embodiments, the description of the apparatus and the device is simple, and reference may be made to the relevant part of the method.

As further be appreciated by those skilled in the art, the units and algorithmic steps in the examples described according to the embodiments disclosed herein can be implemented in forms of electronic hardware, computer software or the combination of the both. To illustrate the interchangeability of the hardware and the software clearly, the components and the steps in the examples are described generally according to functions in the above description. Whether hardware or software is used to implement the functions depends on a specific application and design constraints for the technical solution. For each specific application, different methods may be used by those skilled in the art to implement the described function, and such implementation should not be considered to depart from the scope of this invention.

The steps of the method or algorithm described according to the embodiments disclosed herein can be implemented in forms of hardware, a software module executed by a processor or the combination of the both. The software module may be stored in a Random Access Memory (RAM), a memory, a Read-Only Memory (ROM), an electrically programmable ROM, an electrically erasable programmable ROM, a register, a hardware disk, a movable magnetic disk, CD-ROM or any other forms of storage medium well known in the art.

It should be noted that, the relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, the method, the article or the device. Unless expressively limited, the statement “including a . . . ” does not exclude the case that other similar elements may exist in the process, the method, the article or the device other than enumerated elements.

Hereinabove the method, the apparatus, and the device for detecting abnormality of the electric signal according to the present disclosure are described in detail. The principle and implementations of the present disclosure are described herein with reference to specific examples. The descriptions of the embodiments are merely intended to help understand the method and the key concept of the present disclosure. Those skilled in the art can make modifications to specific implementations and application scopes according to the concept of the present disclosure. Therefore, the specification shall not be construed as a limit to the present disclosure.

1. A method for detecting abnormality of an electric signal, comprising:
sampling the electric signal at each of sampling points in unit sampling intervals, to obtain a sampling value;
counting abnormal sampling points within each of the unit sampling intervals, to acquire a quantity of abnormal points, wherein each of the abnormal sampling points is one of the sampling points at which the sampling value is out of a threshold range of the electric signal;
determining each of the unit sampling intervals, within which the quantity of abnormal points is larger than a quantity-of-abnormal-point threshold, to be an abnormal unit sampling interval;
counting the abnormal unit sampling intervals that are consecutive, to acquire a quantity of consecutive abnormal intervals; and
determining that the electric signal is abnormal, in response to the quantity of consecutive abnormal intervals being greater than a quantity-of-abnormal-interval threshold.

2. The method according to claim 1, wherein before sampling the electric signal at each of sampling points in unit sampling intervals, the method further comprises:
obtaining an original electric signal;
filtering out a direct current component in the original electric signal, to obtain a sinusoidal alternating current component; and
full-wave rectifying the sinusoidal alternating current component, to obtain the electric signal.

3. The method according to claim 2, wherein the obtaining the original signal comprises:
obtaining an original current signal via a current sensor; or
obtaining an original voltage signal via a voltage sensor.

4. The method according to claim 3, wherein determining that the electric signal is abnormal in response to the quantity of consecutive abnormal intervals being greater than the quantity-of-abnormal-interval threshold comprises:
determining that the quantity of consecutive abnormal intervals is greater than the quantity-of-abnormal-interval threshold;
comparing the sampling value of each abnormal sampling point of the abnormal unit sampling intervals with an upper limit and a lower limit of the threshold range;
determining that the abnormal unit sampling intervals are overvoltage or overcurrent sampling intervals, and the electric signal is abnormal due to overvoltage or overcurrent, in response to the sampling value of each abnormal sampling point of the abnormal unit sampling intervals being greater than the upper limit; and
determining that the abnormal unit sampling intervals are undervoltage or undercurrent sampling intervals, and the electric signal is abnormal due to undervoltage or undercurrent, in response to the sampling value of each abnormal sampling point of the abnormal unit sampling intervals being smaller than the lower limit.

5. An apparatus for detecting abnormality of an electric signal, comprising:
a sampling module, configured to sample the electric signal at each of sampling points in unit sampling intervals, to obtain a sampling value;
a first counting module, configured to count abnormal sampling points within each of the unit sampling intervals to acquire a quantity of abnormal points, wherein each of the abnormal sampling points is one of the sampling points at which the sampling value is out of a threshold range of the electric signal;
a second counting module, configured to:
determine each of the unit sampling intervals, within which the quantity of abnormal points is larger than a quantity-of-abnormal-point threshold, to be an abnormal unit sampling interval, and
count the abnormal unit sampling intervals that are consecutive to acquire a quantity of consecutive abnormal intervals; and
a determination module, configured to determine that the electric signal is abnormal in response to the quantity of consecutive abnormal intervals being greater than a quantity-of-abnormal-interval threshold.

6. The apparatus according to claim 5, further comprising:
a filtering module, configured to obtain an original electric signal, and filter out a direct current component in the original electric signal, to obtain a sinusoidal alternating current component; and
a full-wave rectification module, configured to full-wave rectify the sinusoidal alternating current component, to obtain the electric signal.

7. The apparatus according to claim 6, wherein:
the filtering module comprises an original current signal obtaining unit, or an original voltage signal obtaining unit;
the original current signal obtaining unit is configured to obtain an original current signal via a current sensor; and
the original voltage signal obtaining unit is configured to obtain an original voltage signal via a voltage sensor.

8. The apparatus according to claim 7, wherein the determining module comprises:
a determination unit, configured to determine that the quantity of consecutive abnormal intervals is greater than the quantity-of-abnormal-interval threshold;
a comparison unit, configured to compare the sampling value of each abnormal sampling point of the abnormal unit sampling intervals with an upper limit and a lower limit of the threshold range;
an overvoltage or overcurrent determination unit, configured to determine that the abnormal unit sampling intervals are overvoltage or overcurrent sampling intervals and the electric signal is abnormal due to overvoltage or overcurrent, in response to the sampling value of each abnormal sampling point of the abnormal unit sampling intervals being greater than the upper limit; and
an undervoltage or undercurrent determination unit, configured to determine that the abnormal unit sampling intervals are undervoltage or undercurrent sampling intervals and the electric signal is abnormal due to undervoltage or undercurrent, in response to the sampling value of each abnormal sampling point of the abnormal unit sampling intervals being smaller than the lower limit.

9. A device for detecting abnormality of an electric signal, comprising:
a memory, configured to store a computer program; and
a processor;
wherein the computer program when executed by the processor configures the device to implement the method for detecting abnormality of the electric signal according to claim 1.

10. A device for detecting abnormality of an electric signal, comprising:
a memory, configured to store a computer program; and
a processor;
wherein the computer program when executed by the processor configures the device to implement the method for detecting abnormality of the electric signal according to claim 2.

11. A device for detecting abnormality of an electric signal, comprising:
a memory, configured to store a computer program; and
a processor;
wherein the computer program when executed by the processor configures the device to implement the method for detecting abnormality of the electric signal according to claim 3.

12. A device for detecting abnormality of an electric signal, comprising:
a memory, configured to store a computer program; and
a processor;
wherein the computer program when executed by the processor configures the device to implement the method for detecting abnormality of the electric signal according to claim 4.
